(19) United States
(12) Patent Application Publication
(10) Pub. No.: US 2025/0081358 A1
(43) Pub. Date: Mar. 6, 2025

(54) WIRING BOARD

(71) Applicant: SHINKO ELECTRIC INDUSTRIES CO., LTD., Nagano (JP)

(72) Inventor: Takashi NISHIYAMA, Nagano (JP)

(21) Appl. No.: 18/822,905

(22) Filed: Sep. 3, 2024

(30) Foreign Application Priority Data
Sep. 5, 2023 (JP) 2023-143615

(51) Int. Cl. H05K 3/46; H05K 1/11; H05K 3/42

(52) U.S. Cl. CPC H05K 3/4679; H05K 1/114; H05K 3/429; H05K 3/423; H05K 2201/0338; H05K 2201/096; H05K 2203/166

(57) ABSTRACT

A wiring board includes a first insulating layer, a first interconnect layer formed on the first insulating layer, a second insulating layer formed on the first interconnect layer, an opening penetrating the second insulating layer and exposing an upper surface of the first interconnect layer, and a second interconnect layer that is an outermost interconnect layer disposed inside the opening and electrically connected to the first interconnect layer.

### CROSS-REFERENCE TO RELATED APPLICATIONS

This application is based upon and claims priority to Japanese Patent Application No. 2023-143615, filed on Sep. 5, 2023, the entire contents of which are incorporated herein by reference.

### FIELD

Certain aspects of the embodiments discussed herein are related to wiring boards, and methods for manufacturing wiring boards.

### BACKGROUND

Conventionally, there is a known wiring board having interconnect layers and insulating layers that are alternately laminated by a build-up method or the like. In this wiring board, a solder resist layer is formed to cover an outermost interconnect layer, for example. In addition, the solder resist layer is provided with an opening for selectively exposing the outermost interconnect layer (refer to Japanese Laid-Open Patent Publication No. 2019-192885, for example).

However, in the wiring board described above, a positional error may occur between the outermost interconnect layer and the solder resist layer due to constraints on a manufacturing accuracy. Such a positional error is more likely to affect a reliability as a pitch of the outermost interconnect layer becomes narrower.

### SUMMARY

Accordingly, it is an object in one aspect of the embodiments to prevent a positional error between an outermost interconnect layer and an insulating layer provided with an opening that exposes the outermost interconnect layer in a wiring board.

According to one aspect of the embodiments, a wiring board includes a first insulating layer; a first interconnect layer formed on the first insulating layer; a second insulating layer formed on the first interconnect layer; an opening penetrating the second insulating layer and exposing an upper surface of the first interconnect layer; and a second interconnect layer that is an outermost interconnect layer disposed inside the opening and electrically connected to the first interconnect layer.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a cross sectional view illustrating a wiring board according to a first embodiment;

FIG. 2A, FIG. 2B, FIG. 2C, and FIG. 2D are diagrams (part 1) illustrating manufacturing processes of the wiring board according to the first embodiment;

FIG. 3A, FIG. 3B, FIG. 3C, and FIG. 3D are diagrams (part 2) illustrating the manufacturing processes of the wiring board according to the first embodiment;

FIG. 4A, FIG. 4B, and FIG. 4C are diagrams illustrating manufacturing processes of a wiring board according to a comparative example; and

FIG. 5 is a cross sectional view illustrating a wiring board according to a first modification of the first embodiment.

### DESCRIPTION OF EMBODIMENTS

Hereinafter, preferred embodiments of the present disclosure will be described with reference to the accompanying drawings. In the drawings, those parts or constituent elements that are the same are designated by the same reference numerals, and a repeated description of the same parts or constituent elements may be omitted.

### First Embodiment

### [Configuration of Wiring Board]

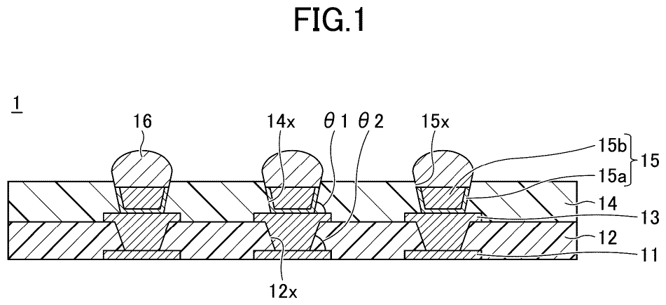

FIG. 1 is a cross sectional view illustrating a wiring board according to a first embodiment. As illustrated in FIG. 1, a wiring board 1 includes an interconnect layer 11, an insulating layer 12, an interconnect layer 13, a solder resist layer 14, an interconnect layer 15, and bumps 16. The wiring board 1 may further include multiple insulating layers and interconnect layers below the interconnect layer 11. The wiring board 1 may or may not include the bumps 16.

In the present embodiment, for sake of convenience, the side of the wiring board 1 provided with the solder resist layer 14 in FIG. 1 may be referred to as an upper side or one side, and the side of the wiring board 1 provided with the interconnect layer 11 may be referred to as a lower side or the other side. In addition, a surface of each portion on the side of the wiring board 1 provided with the solder resist layer 14 may be referred to as an upper surface or one surface, and a surface of each portion on the side of the wiring board 1 provided with the interconnect layer 11 may be referred to as a lower surface or the other surface. However, the wiring board 1 can be used in an upside-down state or can be disposed at an arbitrary angle. Moreover, a plan view refers to a view of an object, viewed from above, in a normal direction with respect to an upper surface of the solder resist layer 14. A planar shape refers to a shape of an object in the plan view, viewed from above, in the normal direction with respect to the upper surface of the solder resist layer 14.

In the wiring board 1, the interconnect layer 11 is embedded in a lower surface of the insulating layer 12. A lower surface of the interconnect layer 11 is exposed from the lower surface of the insulating layer 12, and an upper surface and a side surface of the interconnect layer 11 are covered with the insulating layer 12. The lower surface of the interconnect layer 11 may coincide with the lower surface of the insulating layer 12, for example.

The lower surface of the interconnect layer 11, exposed from the lower surface of the insulating layer 12, is formed in a circular planar shape, for example, and can be used as pad to be connected to another wiring board or the like. The interconnect layer 11 may include an interconnect pattern in addition to the pads. A material used for the interconnect layer 11 may be copper (Cu) or the like, for example. The interconnect layer 11 may have a laminated structure of a plurality of metal layers. A thickness of the interconnect layer 11 may be in a range of approximately 5 μm to approximately 20 μm, for example.

The insulating layer 12 is formed so as to cover the upper surface and the side surface of the interconnect layer 11. A material used for the insulating layer 12 may be a non-photosensitive (thermosetting) epoxy-based insulating resin, a polyimide-based insulating resin, or the like, for example. The material used for the insulating layer 12 may be a photosensitive epoxy-based insulating resin, an acryl-based insulating resin, or the like, for example. A thickness of the insulating layer 12 may be in a range of approximately 10 μm to approximately 40 μm, for example. The insulating layer 12 may include a filler, such as silica (SiO₂) or the like.

The interconnect layer 13 is formed on the insulating layer 12. The interconnect layer 13 is formed to include via interconnects filling via holes 12x penetrating the insulating layer 12 and exposing the upper surface of the interconnect layer 11, and an interconnect pattern formed on an upper surface of the insulating layer 12. The via hole 12x may have an inverted truncated cone shape such that a diameter of the via hole 12x that opens toward the solder resist layer 14 is larger than a diameter of a bottom surface of the via hole 12x formed by the upper surface of the interconnect layer 11. The interconnect layer 13 is electrically connected to the interconnect layer 11 exposed at the bottom of the via hole 12x. A material used for the interconnect layer 13 may be copper (Cu) or the like, for example. A thickness of the interconnect pattern forming the interconnect layer 13 may be in a range of approximately 5 μm to approximately 20 μm, for example.

The solder resist layer 14 is formed on the interconnect layer 13. More specifically, the solder resist layer 14 is a protective insulating layer formed on the insulating layer 12 so as to cover the interconnect layer 13. A material used for the solder resist layer 14 may be a photosensitive insulating resin including a phenol-based resin, a polyimide-based resin, or the like, for example, as a main component thereof. The solder resist layer 14 may include a filler, such as silica (SiO₂) or the like.

The solder resist layer 14 has openings 14x penetrating the solder resist layer 14 and exposing an upper surface of the interconnect layer 13. The opening 14x may have an inverted truncated cone shape such that a diameter of the opening 14x that opens toward the solder resist layer 14 is larger than a diameter of a bottom surface of the opening 14x formed by the upper surface of the interconnect layer 13. A diameter of the opening 14x open toward the solder resist layer 14 may be in a range of approximately 7 μm to approximately 15 μm, for example.

An angle θ1 formed by an inner surface of the opening 14x (that is, the surface of the solder resist layer 14 defining the opening 14x) with respect to the upper surface of the interconnect layer 13 is larger than an angle θ2 formed by an inner surface of the via hole 12x (that is, the surface of the insulating layer 12 defining the via hole 12x) with respect to the upper surface of the interconnect layer 11 in a cross sectional view. The angle θ1 may be in a range of 80 degrees to 90 degrees, for example. By setting the angle θ1 in the range of 80° to 90°, it is possible to form a plurality of openings 14x at a narrow pitch. The pitch of the openings 14x may be approximately 30 μm, for example.

The interconnect layer 15 is an outermost interconnect layer disposed inside the opening 14x, and is electrically connected to the interconnect layer 13. An upper surface of the interconnect layer 15 may coincide with the upper surface of the solder resist layer 14, but is preferably located at a position recessed from the upper surface of the solder resist layer 14 toward the insulating layer 12. That is, recesses 15x, recessed toward the insulating layer 12, are preferably formed in the upper surface of the solder resist layer 14. Thus, the bumps 16 can easily be formed on the interconnect layer 15. A depth of the recess 15x may be in a range of approximately ⅓ to approximately ½ times a diameter an opening of the recess 15x.

The interconnect layer 15 may have a laminated structure having an electrolytic plating layer 15b laminated on a seed layer 15a, for example. The seed layer 15a continuously covers the inner surface of the opening 14x and the upper surface of the interconnect layer 13 exposed inside the opening 14x. That is, the interconnect layer 15 includes the seed layer 15a that forms a side surface and a bottom surface of the interconnect layer 15. The seed layer 15a serves as an adhesion layer that improves adhesion between the solder resist layer 14 and the electrolytic plating layer 15b.

The seed layer 15a is a copper (Cu) layer having a thickness in a range of approximately 100 nm to approximately 350 nm, for example. The seed layer 15a may be a laminated film (or a multi-layer film) having a copper (Cu) layer with a thickness in a range of approximately 100 nm to approximately 300 nm laminated on a titanium (Ti) layer with a thickness in a range of approximately 20 nm to approximately 50 nm, for example. The electrolytic plating layer 15b is a copper (Cu) layer having a thickness in a range of approximately 1 μm to approximately 10 μm, for example. Because the seed layer 15a is extremely thin, the thickness of the electrolytic plating layer 15b may be regarded as the thickness of the entire interconnect layer 15.

### [Method for Manufacturing Wiring Board]

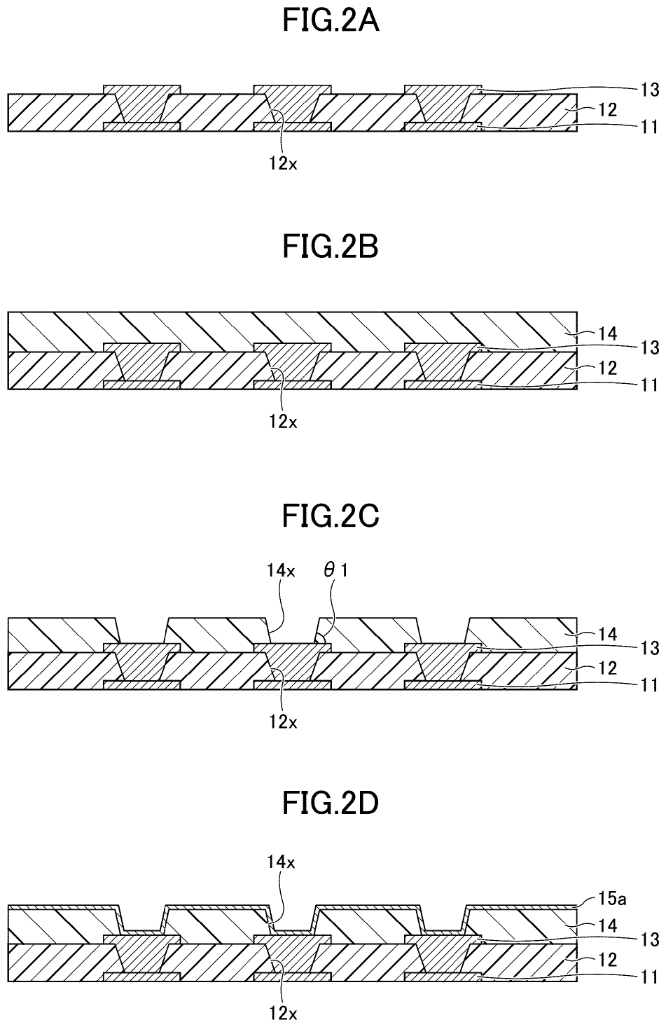

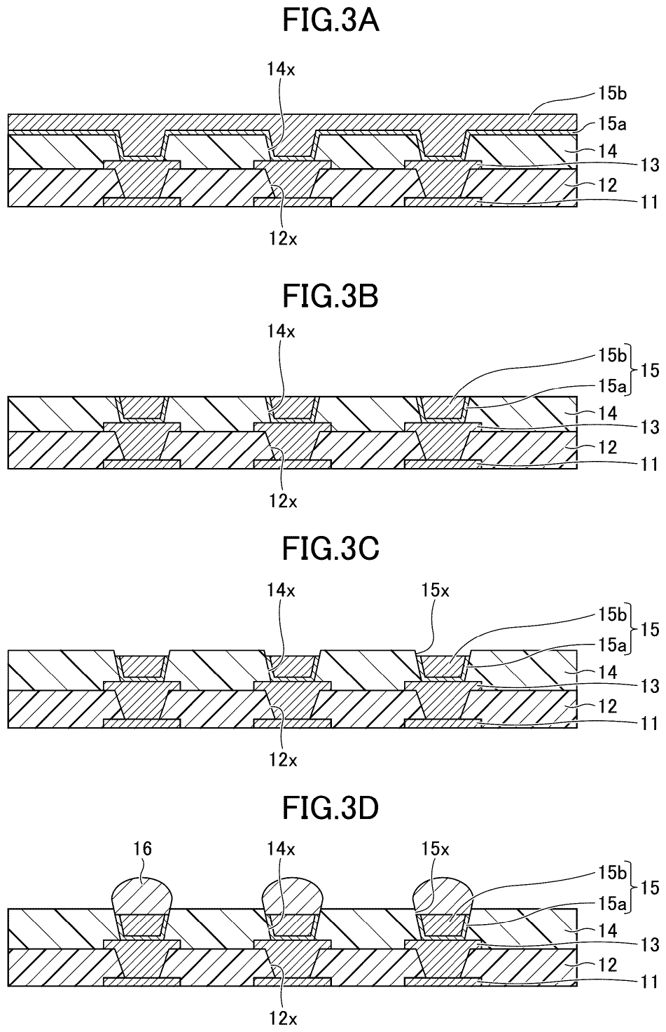

Next, a method for manufacturing the wiring board according to the first embodiment will be described. FIG. 2A through FIG. 3D are diagrams illustrating manufacturing processes of the wiring board according to the first embodiment.

First, in the process (or step) illustrated in FIG. 2A, the interconnect layer 13 is formed on the insulating layer 12 that covers the interconnect layer 11. For example, after the interconnect layer 11 having a predetermined pattern is formed on a support (not illustrated), an insulating resin in a semi-cured state is laminated on an upper surface of the support so as to cover the interconnect layer 11, and is cured to form the insulating layer 12. Then, via holes 12x that penetrate the insulating layer 12 and expose the upper surface of the interconnect layer 11 are formed by laser beam machining using a CO₂ laser or the like. Thereafter, the interconnect layer 13 is formed inside the via holes 12x and on the via holes 12x by a semi-additive method or the like.

Next, in the process (or step) illustrated in FIG. 2B, the solder resist layer 14 is formed on the interconnect layer 13. More specifically, the solder resist layer 14 is formed by laminating a semi-cured insulating resin on the upper surface of the insulating layer 12, so as to cover the interconnect layer 13, and curing the semi-cured insulating resin. The material used for the solder resist layer 14 and the thickness of the solder resist layer 14 are the same as those described above.

Next, in the process (or step) illustrated in FIG. 2C, the openings 14x are formed to penetrate the solder resist layer 14 and expose the upper surface of the interconnect layer 13. The openings 14x can be formed by the laser beam machining, for example. The openings 14x are preferably formed using an excimer laser. Thus, the angle θ1 can be set in a range of 80 degrees to 90 degrees.

Next, in the processes (or steps) illustrated in FIG. 2D through FIG. 3B, the interconnect layer 15, which becomes the outermost interconnect layer and is electrically connected to the interconnect layer 13, is formed inside the openings 14x. First, in the process (or step) illustrated in FIG. 2D, the seed layer 15a is formed on the surface of the solder resist layer 14 including the inner surface of the openings 14x and the upper surface of the interconnect layer 13 exposed inside the openings 14x by electroless plating or sputtering. The material used for the seed layer 15a and the thickness of the seed layer 15a are the same as those described above.

Next, in the process (or step) illustrated in FIG. 3A, the electrolytic plating layer 15b filling the openings 14x and extending on the upper surface of the solder resist layer 14 are formed by electrolytic plating in which power is supplied from the seed layer 15a. The seed layer 15a functions as a power supplying layer, and also functions as an adhesion layer that improves the adhesion between the solder resist layer 14 and the electrolytic plating layer 15b.

Next, in the process (or step) illustrated in FIG. 3B, the upper surface of the electrolytic plating layer 15b is polished to remove the seed layer 15a covering the upper surface of the solder resist layer 14. Thus, the interconnect layer 15 is formed. For example, chemical mechanical polishing (CMP) may be used for the polishing. After the polishing, the upper surface of the solder resist layer 14, an end surface of the seed layer 15a, and the upper surface of the electrolytic plating layer 15b may coincide with one another. A surface roughness Ra of the upper surface of the solder resist layer 14 after polishing may be approximately 20 nm (Ra20 nm), for example.

Next, in the process (or step) illustrated in FIG. 3C, the recesses 15x, recessed toward the insulating layer 12 with respect to the upper surface of the solder resist layer 14, are formed. The recesses 15x may be formed by wet etching, for example. In a case where the seed layer 15a and the electrolytic plating layer 15b are formed of copper (Cu), a ferric chloride aqueous solution, a cupric chloride aqueous solution, an ammonium persulfate aqueous solution, or the like, for example, can be used for the etching.

Next, in the process (or step) illustrated in FIG. 3D, the bumps 16 are formed on the interconnect layer 15. The bumps 16 may be formed by printing cream solder inside the recesses 15x and reflowing the solder, for example. A material used for the solder bump may be an alloy including Pb, an alloy of Sn and Cu, an alloy of Sn and Ag, an alloy of Sn, Ag, and Cu, or the like, for example. This process (or step) may be performed, as required. The wiring board 1 is completed by performing the processes (steps) described above.

### Comparative Example

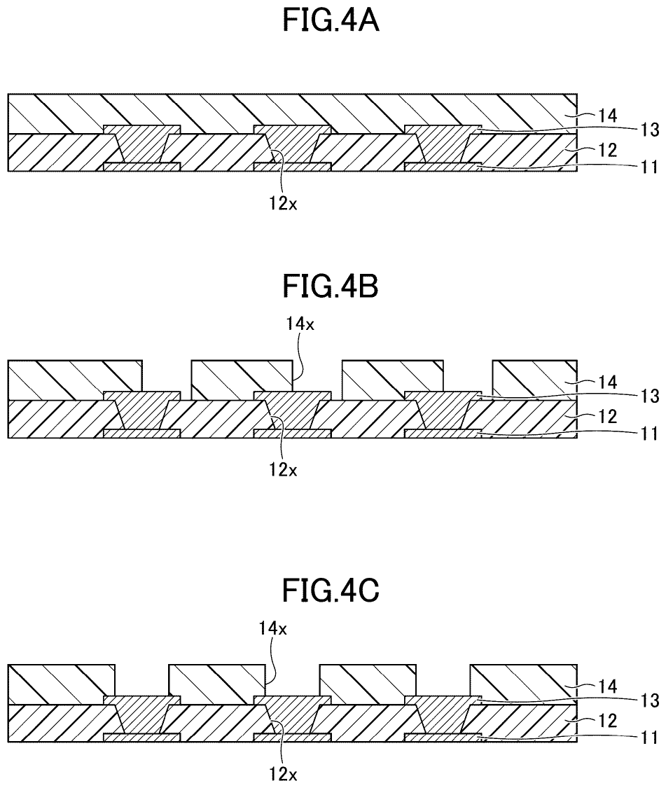

FIG. 4A, FIG. 4B, and FIG. 4C are diagrams illustrating manufacturing processes of a wiring board according to a comparative example. First, in the process (or step) illustrated in FIG. 4A, the process (or step) similar to that illustrated in FIG. 2B is performed. In this comparative example, the material used for the solder resist layer 14 is a photosensitive insulating resin.

Next, in the process (or step) illustrated in FIG. 4B, the solder resist layer 14 is exposed and developed, thereby forming the openings 14x that expose portions of the upper surface of the interconnect layer 13 in the solder resist layer 14 (using photolithography).

By design, the openings 14x should be formed at the designed positions illustrated in FIG. 4C, but in the process (or step) illustrated in FIG. 4B, the positions where the openings 14x are formed become shifted from the designed positions due to the constraints on the manufacturing accuracy. That is, a positional error occurs between the outermost interconnect layer 13 and the openings 14x. Such a positional error is likely to affect the reliability as the pitch of the interconnect layers 13 becomes narrower. For example, when the adjacent interconnect layers 13 are exposed inside a single opening 14x, the adjacent interconnect layers 13 may become short-circuited by the solder or the like formed on the interconnect layers 13.

In contrast, according to the wiring board 1, the openings 14x are formed in the solder resist layer 14, and the interconnect layer 15 is thereafter formed inside the openings 14x. For this reason, in principle, no positional error occurs between the outermost interconnect layer 15 and the solder resist layer 14 covering the outermost interconnect layer 15. Hence, even when the pitch of the interconnect layers 13 becomes narrow, the short-circuiting of the adjacent interconnect layers 15 due to the solder or the like formed on the interconnect layers 15 in the comparative example described above is unlikely to occur in the present embodiment.

Further, in the comparative example illustrated in FIG. 4B, the outermost interconnect layer 13 has stepped portions at the side surface thereof and at the inner surface thereof. For example, in the cross sectional view, a connecting portion between the side surface of the interconnect pattern located on the upper surface of the insulating layer 12 and the lower surface of the interconnect pattern on the upper surface of the insulating layer 12 is bent and is not linear, thereby forming the stepped portion. In addition, a connecting portion between the lower surface of the interconnect pattern located on the upper surface of the insulating layer 12 and a surface of the via interconnect filling the via hole 12x and making contact with the inner surface of the via hole 12x is bent and is not linear, thereby forming the stepped portion. Accordingly, in the outermost interconnect layer 13, when the side surface and the inner surface are not linear but have a bent portion, stress concentrates at the bent portion, and haloing is likely to occur. The haloing is destruction or peeling caused by mechanical or chemical factors. The haloing is caused by penetration of a chemical solution or effects of heat, and when an interface or a stepped portion is present, the haloing may occur from the interface or the stepped portion which act as a source.

In contrast, according to the wiring board 1, the inner surface of the outermost interconnect layer 15 is linear and does not have a bent portion. For this reason, there is no portion where stress is likely to concentrate, and the haloing is unlikely to occur.

In the structure of the comparative example illustrated in FIG. 4B, a seed layer or the like serving as an adhesion layer is not present in a portion where the solder resist layer 14 and the interconnect layer 13 make contact with each other. For this reason, the adhesion between the solder resist layer 14 and the interconnect layer 13 is poor, and the haloing is likely to occur.

In contrast, in the wiring board 1, the solder resist layer 14 makes contact with the electrolytic plating layer 15b via the seed layer 15a serving as the adhesion layer. For this reason, the adhesion between the solder resist layer 14 and the electrolytic plating layer 15b is good, and the haloing is less likely to occur.

### First Modification of First Embodiment

In a first modification of the first embodiment, an example of the wiring board includes an additional insulating layer. In the first modification of the first embodiment, a description of those constituent elements or parts that are the same as those of the embodiment described above may be omitted.

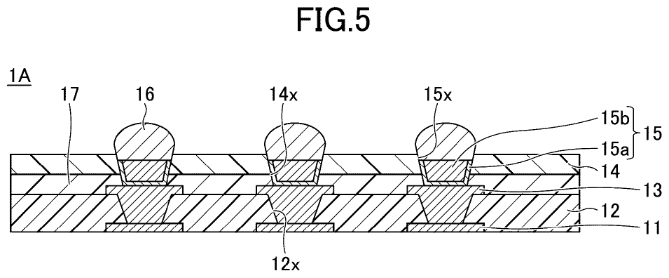

FIG. 5 is a cross sectional view illustrating the wiring board according to the first modification of the first embodiment. As illustrated in FIG. 5, a wiring board 1A differs from the wiring board 1 in that an additional insulating layer 17 is provided.

In the wiring board 1A, the insulating layer 17 is disposed between the insulating layer 12 and the solder resist layer 14. The insulating layer 17 covers the interconnect layer 13. A material used for the insulating layer 17 may be the same as the material used for the insulating layer 12, for example. The insulating layer 17 may have an arbitrary thickness capable of covering the interconnect pattern of the interconnect layer 13, and may be in a range of approximately 5 μm to approximately 15 μm, for example, at a position on the interconnect pattern of the interconnect layer 13.

The openings 14x continuously penetrate the solder resist layer 14 and the insulating layer 17, and expose the upper surface of the interconnect layer 13. The shape of the openings 14x may be the same as that of the first embodiment.

Accordingly, the insulating layer 17 may be provided to cover the interconnect layer 13. By providing the insulating layer 17, good adhesion can be achieved between the insulating layer 17 and the interconnect layer 13. The adhesion between the insulating layer 17 and the interconnect layer 13 is stronger than the adhesion between the solder resist layer 14 and the interconnect layer 13, because a chemical bond between the insulating layer 17 and the interconnect layer 13 is stronger than a chemical bond between the solder resist layer 14 and the interconnect layer 13.

According to the disclosed technique, it is possible to prevent a positional error between an outermost interconnect layer and an insulating layer provided with an opening that exposes the outermost interconnect layer in a wiring board.

Various aspects of the subject-matter described herein may be set out non-exhaustively in the following numbered clauses:

1. A method for manufacturing a wiring board, comprising:
forming a first interconnect layer on a first insulating layer;
forming a second insulating layer over the first interconnect layer;
forming an opening penetrating the second insulating layer and exposing an upper surface of the first interconnect layer; and
forming a second interconnect layer that is an outermost interconnect layer disposed inside the opening and electrically connected to the first interconnect layer.

2. The method for manufacturing the wiring board according to clause 1, wherein the forming the second interconnect layer includes:
forming a seed layer serving as an adhesion layer on a surface of the second insulating layer including an inner surface of the opening and on the upper surface of the first interconnect layer exposed inside the opening;
forming an electrolytic plating layer filling the opening and extending on an upper surface of the second insulating layer by electrolytic plating in which power is supplied from the seed layer; and
polishing an upper surface of the electrolytic plating layer to remove the seed layer covering the upper surface of the second insulating layer.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A wiring board comprising:
a first insulating layer;
a first interconnect layer formed on the first insulating layer;
a second insulating layer formed on the first interconnect layer;
an opening penetrating the second insulating layer and exposing an upper surface of the first interconnect layer; and
a second interconnect layer that is an outermost interconnect layer disposed inside the opening and electrically connected to the first interconnect layer.

2. The wiring board as claimed in claim 1, wherein the second interconnect layer includes a seed layer that forms a side surface and a bottom surface and serves as an adhesion layer.

3. The wiring board as claimed in claim 1, wherein the second insulating layer covers the first interconnect layer.

4. The wiring board as claimed in claim 1, further comprising:
a third insulating layer covering the first interconnect layer and disposed between the first insulating layer and the second insulating layer,
wherein the opening penetrates the second insulating layer and the third insulating layer and exposes the upper surface of the first interconnect layer.

5. The wiring board as claimed in claim 1, wherein an upper surface of the second interconnect layer is located at a position recessed more toward the first insulating layer than an upper surface of the second insulating layer.

6. The wiring board as claimed in claim 1, wherein the opening has an inverted truncated cone shape such that a diameter of the opening that opens toward an upper surface of the second insulating layer is larger than a diameter of a bottom surface of the opening formed by the upper surface of the first interconnect layer.

7. The wiring board as claimed in claim 6, wherein:
the first interconnect layer includes a via interconnect filling a via hole that penetrates the first insulating layer,
the via hole has an inverted truncated cone shape such that a diameter of the via hole that opens toward the second insulating layer is larger than a diameter of a bottom surface of the via hole formed by an upper surface of a lower interconnect layer, and
an angle formed by an inner surface of the opening with respect to the upper surface of the first interconnect layer is larger than an angle formed by an inner surface of the via hole with respect to the upper surface of the lower interconnect layer in a cross sectional view.

8. The wiring board as claimed in claim 1, wherein the second insulating layer is a solder resist layer.
